(19) United States
(12) Patent Application Publication
(10) Pub. No.: US 2008/0272401 A1
(43) Pub. Date: Nov. 6, 2008

(54) Inverted Junction Field Effect Transistor and Method of Forming Thereof

(75) Inventors: Madhu Vora, Los Gatos, CA (US); Ashok K. Kapoor, Palo Alto, CA (US)

Correspondence Address: BAKER BOTTS L.L.P., 2001 ROSS AVENUE, SUITE 600, DALLAS, TX, 75201-2980, US

(73) Assignee: DSM Solutions, Inc., Los Gatos, CA (US)

(21) Appl. No.: 11/743,884

(22) Filed: May 3, 2007

(51) Int. Cl. H01L 29/808; H01L 21/337

(52) U.S. Cl. 257/256; 438/186; 257/E29.312; 257/E21.445

(57) ABSTRACT

A junction field effect transistor includes a substrate and a well region on the substrate. A channel region lies in the well region. A source region lies in the channel region. A drain region lies in the channel region and apart from the source region. A gate region is isolated from the source, drain, and channel regions. The gate region is in contact with a portion of the well region.

### TECHNICAL FIELD OF THE INVENTION

The present invention relates in general to semiconductor design and manufacturing and more particularly to an inverted junction field effect transistor and method of making thereof.

### BACKGROUND OF THE INVENTION

A conventional junction field effect transistor may be formed in an n-type substrate with n-type source, drain, and channel regions. A p-type gate region is typically formed overlaying the channel region between the source and drain regions. The critical dimension of the n-channel junction field effect transistor is the gate length. The gate length is determined by a minimum contact hole dimension plus necessary overlap to ensure that the gate region encloses the gate contact. This feature of junction field effect transistor construction limits the performance of a resulting device since the channel length is substantially larger than the minimum feature size. In addition, the capacitances of the vertical sidewalls of the gate diffusion to the drain and source regions are quite large. The gate to drain sidewall capacitance forms the Miller capacitance that significantly limits the performance of the device at high frequencies.

Therefore, it is desirable to have an integrated circuit and device structure that reduces gate capacitance and provides for a smaller channel length.

### SUMMARY OF THE INVENTION

From the foregoing, it may be appreciated by those skilled in the art that a need has arisen for a junction field effect transistor and manufacturing technique suited for submicron dimensions that reduces the capacitances provided in conventional junction field effect transistor designs. In accordance with the present invention, an inverted junction field effect transistor and method of forming thereof are provided that substantially eliminate or greatly reduce disadvantages and problems associated with conventional junction field effect transistor technology.

According to an embodiment of the present invention, there is provided a junction field effect transistor that includes a source region and a drain region separated by a channel region. A gate region is isolated from the source, drain, and channel regions. A well region within a substrate provides a gate to channel junction system on the substrate side of the device.

The present invention provides various technical advantages over conventional junction field effect transistors and fabrications thereof. Some of these technical advantages are shown and described in the description of the present invention. Certain embodiments of the present invention may enjoy some, all, or none of these advantages. Other technical advantages may be readily apparent to one skilled in the art from the following figures, description, and claims.

### BRIEF DESCRIPTION OF THE DRAWINGS

For a more complete understanding of the present invention and the advantages thereof, reference is made to the following description taken in conjunction with the accompanying drawings, wherein like reference numerals represent like parts, in which:

FIG. 1 illustrates a top view of a junction field effect transistor;

FIGS. 2A-2E illustrate a process for forming the junction field effect transistor;

FIGS. 3A-3D illustrate channel activity during operation of the junction field effect transistor;

FIG. 4 illustrates an alternative structure for the junction field effect transistor;

FIG. 5 illustrates another alternative structure for the junction field effect transistor.

### DETAILED DESCRIPTION OF THE INVENTION

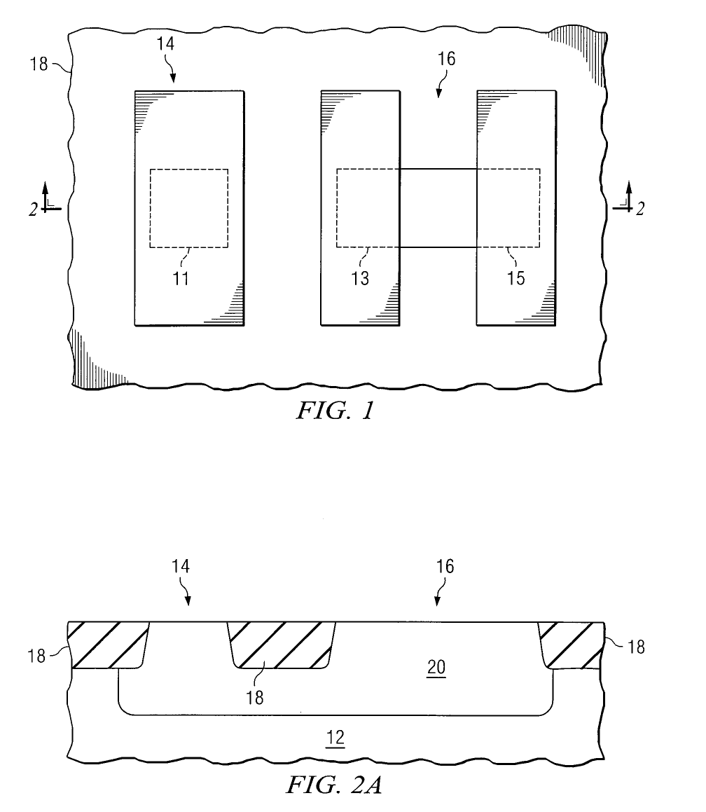

FIG. 1 shows a top view of a transistor 10. Transistor 10 is a junction field effect transistor with a first active region 14 and a second active region 16 formed in a substrate 12 (not shown here). First active region 14 is associated with a gate 11 of transistor 10. Second active region 16 is associated with a drain 13 and a source 15 of transistor 10. An isolation layer 18 provides isolation between first active region 14 with gate 11 and second active region 16 with drain 13 and source 15.

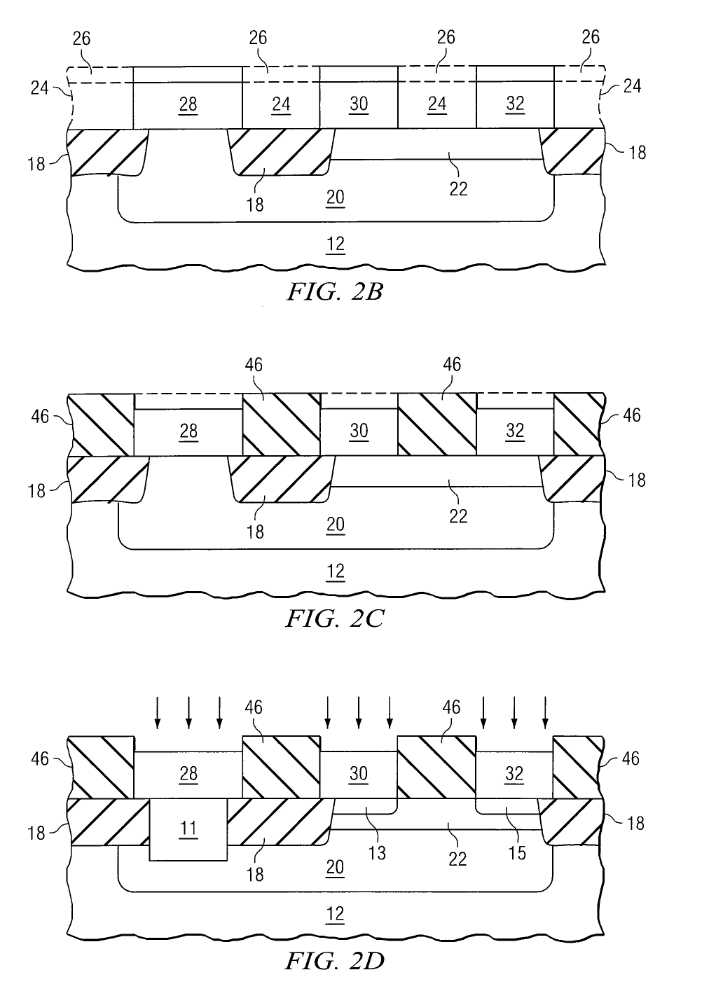

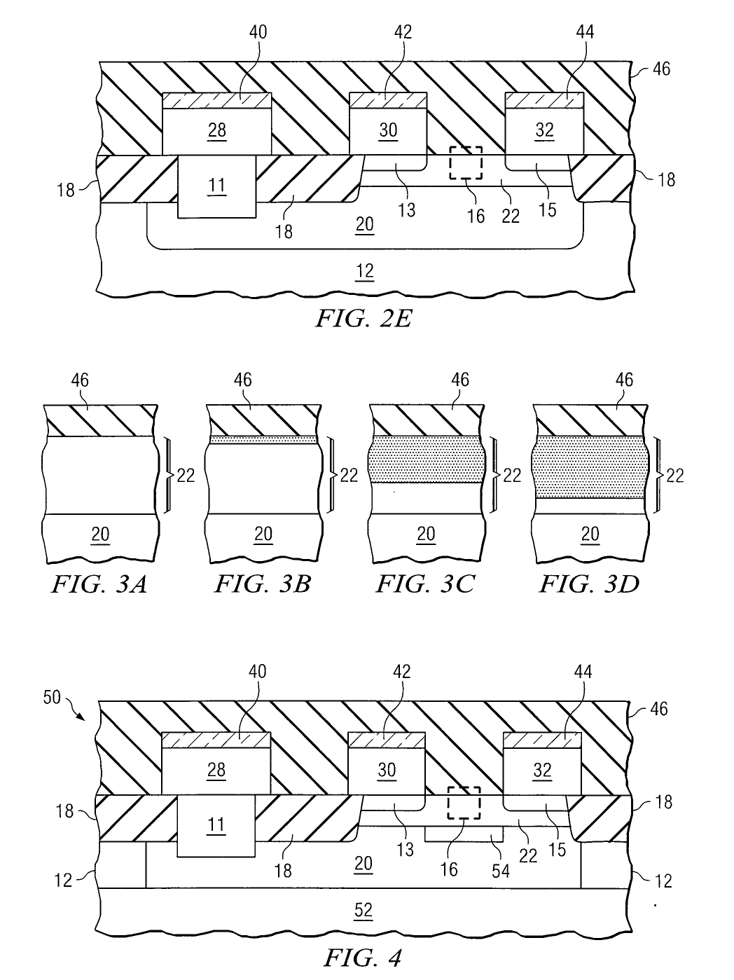

FIGS. 2A-2E show the fabrication process involved in forming transistor 10 in accordance with an embodiment of the present invention. Though described in a certain order, individual process steps may be performed in a different order while still achieving the same structure. Though the process steps show the creation of an n-type JFET, a p-type JFET may also be created by changing the materials used during the fabrication process.

In FIG. 2A, transistor 10 starts out as a substrate 12. Two active regions or islands 14 and 16 are created and surrounded by an isolation layer 18. Active regions 14 and 16 defined by isolation layer 18 may be created using any conventional fabrication process to include Shallow Trench Isolation (STI). A well region 20 is created below and around active regions 14 and 16. Well region 20 may be created through appropriate p-type doping of substrate 12.

In FIG. 2B, an n-type channel 22 is created in well region 20 below active region 16. Appropriate photoresist masks (not shown) are used to precisely provide a window for implanting channel 22 into well region 20. An interface layer 24 and a nitride layer 26 are formed on the entire transistor 10. Interface layer 24 may be formed using polysilicon to provide a polysilicon layer.

In FIG. 2C, interface layer 24 and nitride layer 26 are appropriately patterned to form gate interface region 28, drain interface region 30, and source interface region 32. A thin thermal oxide layer (not shown) may be grown to provide protection for the transistor due to over-etching. A passivation layer 46 is then formed across transistor 10. Passivation layer 46 may be formed by an oxide chemical vapor deposition technique and planarized using a chemical mechanical polish technique.

In FIG. 2D, nitride layer 26 is then etched away. Gate interface region 28 is appropriately implanted with a p-type dopant having a doping level greater than that of well region 20. Boron is an example of a p-type dopant used for gate interface region 28. The p-type dopant of gate interface region 28 is diffused into well region 20 and below isolation layer 18 in order to establish gate 11. Similarly, drain interface region 30 and source interface region 32 are appropriately implanted with an n-type dopant having a doping level greater than that of channel 22. Arsenic is an example of an n-type dopant used for drain interface region 30 and source interface region 32. The n-type dopant of drain interface region 30 and source interface region 32 is appropriately diffused partially into channel 22 in order to establish drain 13 and source 15.

In FIG. 2E, a gate interconnect region 40 is formed on gate interface region 28. A drain interconnect region 42 is formed on drain interface region 30. A source interconnect region 44 is formed on source interface region 32. An example material for each interconnect region is silicide.

FIGS. 3A-3D show channel activity during operation of transistor 10. Well region 20, channel 22, and passivation layer 46 are shown. In the example shown, drain voltage VDD is maintained at 0.1V. FIG. 3A shows that channel 22 is fully depleted when 0.0V is applied to gate 11 when 0.0V is at source 13. As a result, there is no drain to source current. As the gate to source voltage VGS increases, channel 22 opens to provide drain to source current.

The structure of transistor 10 eliminates the gate between the source and the drain on top of the channel and provides a single gate connection to the bottom of the channel. Gate 11 of transistor 10 lies away and isolated from drain 13, source 15, and channel 22 interface junctions. As can be seen, gate 11 contacts a bottom side of channel 22 and a top side of channel 22 is terminated by passivation layer 46. The top portion of channel 22 is terminated by passivation layer 46 to eliminate any capacitances provided in conventional junction field effect transistor designs where the gate is formed on top of the channel between the drain and the source. In addition, with the space saved from eliminating the gate between the drain and the source, the length of the channel can be made smaller. Such a structure can provide significantly smaller than minimum lithography limits leading to high transconductance. Also, the height of the polysilicon interface regions eliminates any corner capacitance between the gate and the drain. Thus, the corner capacitance between the gate and the drain, typically found in conventional transistor structures, is eliminated due to the isolation of the gate from the drain. Gate capacitance is significantly smaller than typical transistor structures, achieving as much as a factor of 10 reduction in capacitance.

FIG. 4 shows an alternative structure 50 for transistor 10. Structure 50 uses a Silicon on Insulator (SOI) implementation. For structure 50, substrate 12 is formed on an insulator 52 prior to the above described fabrication process. In addition, another heavily doped well layer 54 is formed to lie beneath channel region 22. Well layer 54 may be formed after the gate interface region 28, drain interface region 30, and source interface region 32 discussed above are established. Well layer 54 is implanted with a p-type dopant at an energy such that a peak of implant is deep enough so as not to affect channel region 22.

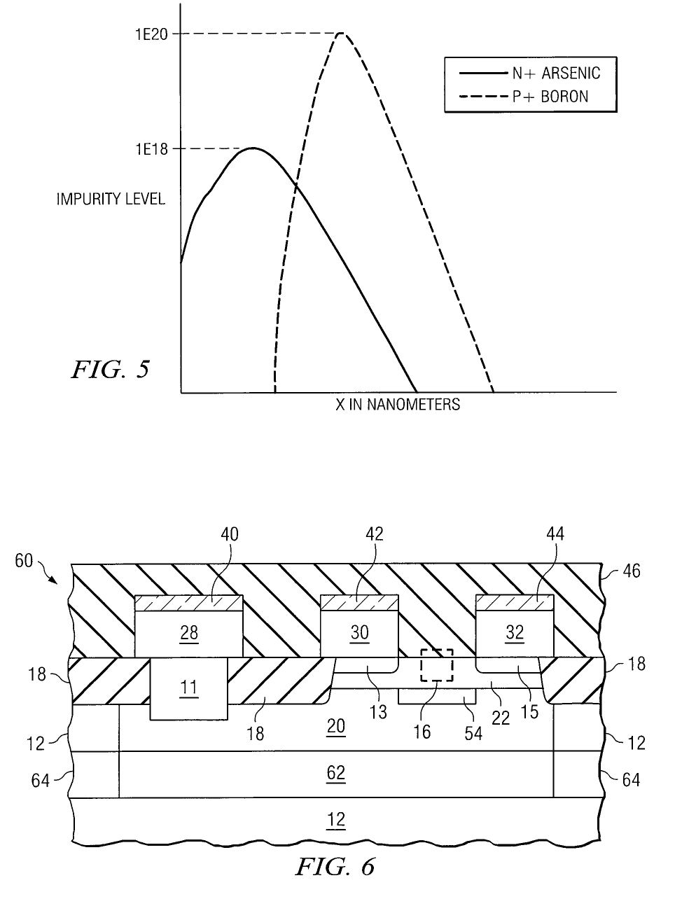

FIG. 5 shows a doping profile for well layer 54 as compared to channel region 22. Channel region 22 is implanted at a low energy level using a medium dose of an n-type dopant. Well layer 54 is implanted at a high energy level using a high dose of a p-type dopant. The doping profile shows a peak impurity level of 1×10¹⁸ atoms/cm² for channel region 22 at a depth of about 30 nanometers. The doping profile shows a peak impurity level of 1×10² atoms/cm² for well layer 54 at a depth of about 60 nanometers. The p-n junction of the structure is at a depth of about 45 nanometers. The use of SOI helps lower the gate to substrate capacitance. The addition of well layer 54 helps to reduce gate to drain capacitance.

FIG. 6 illustrates another alternative structure 60 for transistor 10. Structure 60 has an intrinsic region 62 between well region 20 and substrate 12. Interface layers 64 are implanted with an n-type dopant to provide continuity with substrate 12 outside of the active area of transistor 10. Intrinsic region 62 is implanted with an n-type dopant having a doping level less than substrate 12 and interface layers 64 to help reduce gate to substrate capacitance. Well region 20 is also appropriately implanted to help reduce well to substrate capacitance which also assists in reducing gate to substrate capacitance. Structure 60 also includes well layer 54 as discussed above to help reduce gate to drain capacitance.

Thus, it is apparent that there has been provided, in accordance with the present invention, a junction field effect transistor and method of forming thereof that satisfies the advantages set forth above. Although the present invention has been described in detail, various changes, substitutions, and alterations may be readily ascertainable by those skilled in the art and may be made herein without departing from the spirit and scope of the present invention as set out in the appended claims. Moreover, the present invention is not intended to be limited in any way by any statement made herein that is not otherwise reflected in the following claims.

What is claimed is:

1. A junction field effect transistor comprising:
a substrate;
a well region in the substrate;
a channel region in the well region;
a source region in the channel region;
a drain region in the channel region and apart from the source region;
a gate region isolated from junctions at the source, drain, and channel regions, the gate region in contact with a portion of the well region.

2. The transistor of claim 1, wherein the well region provides a conductivity path between the gate region and a bottom of the channel region.

3. The transistor of claim 1, wherein the source, drain, and channel regions have a first conductivity type and the gate and well regions have a second conductivity type.

4. The transistor of claim 3, wherein the source and drain regions have a higher doping level than the channel region and the gate region has a higher doping level than the well region.

5. The transistor of claim 3, wherein the first conductivity type is an n-type and the second conductivity type is a p-type.

6. The transistor of claim 3, wherein the first conductivity type is a p-type and the second conductivity type is an n-type.

7. The transistor of claim 1, wherein the gate, source, and drain regions have surfaces at a same level.

8. The transistor of claim 1, further comprising:
an isolation oxide layer separating the gate region from the source, drain, and channel regions.

9. The transistor of claim 8, further comprising:
a gate interface region overlying the gate region;
a source interface region overlying the source region;
a drain interface layer overlying the drain region.

10. The transistor of claim 9, further comprising:
an interconnect layer overlying the gate, source, and drain interface regions.

11. The transistor of claim 10, further comprising:
a passivation layer overlying the isolation layer, the gate interface region, the source interface region, the drain interface region, and the channel region.

12. The transistor of claim 11, wherein a top of the channel region is terminated by the passivation layer.

13. A method of fabricating a junction field effect transistor, comprising:
providing a substrate;
forming a well region in the substrate;
forming a channel region on the well region;
forming a source region in the channel region;
forming a drain region in the channel region and apart from the source region;
forming a gate region isolated from junctions at the source, drain, and channel regions, and in contact with a portion of the well region.

14. The method of claim 13, wherein the well region provides a conductivity path between the gate region and a bottom of the channel region.

15. The method of claim 13, wherein the source, drain, and channel regions are formed with a first conductivity type and the gate and well regions are formed with a second conductivity type.

16. The method of claim 15, wherein the source and drain regions have a higher doping level than the channel region and the gate region has a higher doping level than the well region.

17. The method of claim 15, wherein the first conductivity type is an n-type and the second conductivity type is a p-type.

18. The method of claim 15, wherein the first conductivity type is a p-type and the second conductivity type is an n-type.

19. The method of claim 13, wherein the gate, source, and drain regions are formed with surfaces at a same level.

20. The method of claim 13, further comprising:
forming an isolation oxide layer separating the gate region from the source, drain, and channel regions.

21. The method of claim 20, further comprising:
forming a gate interface region overlying the gate region;
forming a source interface region overlying the source region;
forming a drain interface layer overlying the drain region.

22. The method of claim 21, further comprising:
forming an interconnect layer overlying the gate, source, and drain interface regions.

23. The method of claim 22, further comprising:
forming a passivation layer overlying the isolation layer, the gate interface region, the source interface region, the drain interface region, and the channel region.

24. The method of claim 23, wherein a top of the channel region is terminated by the passivation layer.
